(19) United States
(12) Patent Application Publication
(10) Pub. No.: US 2026/0068470 A1
(43) Pub. Date: Mar. 5, 2026

(54) DISPLAY DEVICE AND ELECTRONIC DEVICE INCLUDING THEREOF

(71) Applicant: Samsung Display Co., Ltd., Yongin-si (KR)

(72) Inventors: Dong Chul SHIN, Yongin-si (KR); Soo Bin KIM, Yongin-si (KR); Yong Seok KIM, Yongin-si (KR); Ji Young NAM, Yongin-si (KR); Hae Ju YUN, Yongin-si (KR); Jong Cheon LEE, Yongin-si (KR)

(21) Appl. No.: 19/177,138

(22) Filed: Apr. 11, 2025

(30) Foreign Application Priority Data
Aug. 29, 2024 (KR) 10-2024-0116451

(51) Int. Cl. H10K 59/35; G02B 3/08; H10K 59/121; H10K 59/131; H10K 59/80

(52) U.S. Cl. CPC H10K 59/353; H10K 59/121; H10K 59/131; H10K 59/879; G02B 3/08; H10K 59/351

(57) ABSTRACT

A display device includes: a plurality of display areas; and a first transmissive area between the plurality of display areas and configured to transmit light traveling from outside, wherein each of the plurality of display areas includes: a first sub-display area comprising first sub-pixels configured to emit first light; a second sub-display area comprising second sub-pixels configured to emit second light; a third sub-display area comprising third sub-pixels configured to emit third light; and a fourth sub-display area comprising fourth sub-pixels configured to emit fourth light.

### CROSS-REFERENCE TO RELATED APPLICATION

The present application claims priority to and the benefit of Korean Patent Application No. 10-2024-0116451, filed on Aug. 29, 2024, in the Korean Intellectual Property Office, the entire disclosure of which is incorporated herein by reference.

### BACKGROUND

### 1. Field

The present disclosure relates to a display device and an electronic device including thereof.

### 2. Description of the Related Art

As the information society evolves, various display devices have been developed to display information. For example, an augmented reality (AR) device is a display device that superimposes a virtual image on a real-world image seen by the user's eyes.

In order for an augmented reality device to provide a real-world image along with a virtual image, it is important to implement the virtual image so that the luminance and resolution of the virtual image are close to those of the real-world image. To this end, research is ongoing to increase the luminance and resolution of the virtual image that is incident on the user's eyes.

The above information disclosed in this Background section is only for enhancement of understanding of the background and therefore the information discussed in this Background section does not necessarily constitute prior art.

### SUMMARY

Aspects of the present disclosure include a display device that displays virtual images with high luminance and resolution to a user.

According to some embodiments of the present disclosure, provided a display device including a plurality of display areas, and a first transmissive area between the plurality of display areas and transmitting light traveling from an outside. According to some embodiments, each of the plurality of display areas may include a first sub-display area including first sub-pixels emitting first light, a second sub-display area including second sub-pixels emitting second light, a third sub-display area including third sub-pixels emitting third light, and a fourth sub-display area including fourth sub-pixels emitting fourth light.

According to some embodiments, each of the plurality of display areas may include a first half-transmissive area between the first sub-display area and the second sub-display area and transmitting a part of light traveling from the outside, a second half-transmissive area between the first sub-display area and the third sub-display area and transmitting a part of light traveling from the outside, a third half-transmissive area between the third sub-display area and the fourth sub-display area and transmitting a part of light traveling from the outside, and a fourth half-transmissive area between the second sub-display area and the fourth sub-display area and transmitting a part of light traveling from the outside.

According to some embodiments, each of the plurality of display areas may further include a second transmissive area. According to some embodiments, the second transmissive area may be between the first half-transmissive area and the third half-transmissive area, and between the second half-transmissive area and the fourth half-transmissive area, and transmitting light traveling from the outside.

According to some embodiments, each of the plurality of display areas may further include a first lower sub-metalens in the first sub-display area and including first nanostructures having a first spacing, a first width, and a first height, and a first upper sub-metalens overlapping the first lower sub-metalens and including second nanostructures having a second spacing, a second width, and a second height.

According to some embodiments, each of the plurality of display areas may further include a second lower sub-metalens in the second sub-display area and including third nanostructures having a third spacing, a third width, and a third height, and a second upper sub-metalens overlapping the second lower sub-metalens and including fourth nanostructures having a fourth spacing, a fourth width, and a fourth height.

According to some embodiments, each of the plurality of display areas may further include a third lower sub-metalens in the third sub-display area and including fifth nanostructures having a fifth spacing, a fifth width, and a fifth height, and a third upper sub-metalens overlapping the third lower sub-metalens and including sixth nanostructures having a sixth spacing, a sixth width, and a sixth height.

According to some embodiments, each of the plurality of display areas may further include a fourth lower sub-metalens in the fourth sub-display area and including seventh nanostructures having a seventh spacing, a seventh width, and a seventh height, and a sixth upper sub-metalens overlapping the fourth lower sub-metalens and including eighth nanostructures having an eighth spacing, an eighth width, and an eighth height.

According to some embodiments, each of the plurality of display areas may further include a first scan driver on a first side of the first sub-display area, a second scan driver on a second side of the second sub-display area, a third scan driver on a first side of the third sub-display area, and a fourth scan driver on a second side of the fourth sub-display area. According to some embodiments, a first side of the second sub-display area may face a second side of the first sub-display area that is opposite to the first side, and a first side of the fourth sub-display area may face a second side of the third sub-display area that is opposite to the first side.

According to some embodiments, the display device may further include first scan lines extending in a first direction and connected to the first sub-pixels, the second sub-pixels, the first scan driver and the second scan driver, and second scan lines extending in the first direction and connected to the third sub-pixels, the fourth sub-pixels, the third scan driver, and the fourth scan driver.

According to some embodiments, the first scan lines may be in the first half-transmissive area, and the second scan lines may be in the third half-transmissive area.

According to some embodiments, the display device may further include a data driver spaced apart from the plurality of display areas and the first transmissive area.

According to some embodiments, the display device may further include first data lines extending in a second direction and connected to the first sub-pixels, the third sub-pixels, and the data driver, and second data lines extending in the second direction and connected to the second sub-pixels, the fourth sub-pixels, and the data driver.

According to some embodiments, the first data lines may be in the second half-transmissive area, and the second data lines may be in the fourth half-transmissive area.

According to some embodiments of the present disclosure, a display device includes a plurality of display areas and a first transmissive area between the plurality of display areas, the device including a first substrate, a light-blocking layer on the first substrate in some of the plurality of display areas, at least one thin-film transistor, scan lines and data lines on the light-blocking layer, a planarization film on the thin-film transistor, the scan lines and the data lines, a plurality of light emitting areas on the planarization film and each comprising a first electrode, an emissive layer and a second electrode, an encapsulation layer on the light emitting areas, a plurality of lower metalenses on the encapsulation layer in each of the plurality of display areas, a second substrate on the plurality of lower metalenses, and a plurality of upper metalenses on the second substrate.

According to some embodiments, the display device may further include a refractive-index compensation layer that is between the first substrate and the second substrate in the first transmissive area and has a refractive index equal to that of the first substrate.

According to some embodiments, the plurality of display areas may include a plurality of sub-display areas, a plurality of half-transmissive areas, and a second transmissive area. According to some embodiments, the refractive-index compensation layer may be further in the second transmissive area.

According to some embodiments, the refractive-index compensation layer may not overlap with the plurality of sub-display areas and the plurality of half-transmissive areas.

According to some embodiments, the display device may further include a bonding portion between the first substrate and the second substrate to bond the first substrate with the second substrate.

According to some embodiments, the bonding portion may be between one of the sub-display areas and the second transmissive area, and between one of the half-transmissive areas and the second transmissive area.

According to some embodiments, the bonding portion may be further at an edge of each of the plurality of display areas.

According to some embodiments of the present disclosure, an electronic device includes a display device, the display device including a plurality of display areas, and a first transmissive area between the plurality of display areas and transmitting light traveling from an outside. According to some embodiments, each of the plurality of display areas may include a first sub-display area comprising first sub-pixels emitting first light, a second sub-display area comprising second sub-pixels emitting second light, a third sub-display area comprising third sub-pixels emitting third light, and a fourth sub-display area comprising fourth sub-pixels emitting fourth light.

These and other aspects and characteristics of some embodiments of the present disclosure will become more apparent to those of ordinary skill in the art upon review of the Detailed Description and Claims to follow.

According to some embodiments of the present disclosure, augmented reality can be implemented at a lower resolution than a waveguide augmented reality display device by arranging light-emitting elements where lenses of the augmented reality device are located. For example, the power consumption for the luminance of the display device can be relatively reduced because there is no luminance reduction due to diffraction occurring in the waveguide augmented reality display device.

According to some embodiments of the present disclosure, the display device can relatively reduce the fabrication cost compared to an alternative silicon wafer-based display device by using a glass substrate.

According to some embodiments of the present disclosure, it may be possible to relatively reduce the difficulty of the process of fabricating a display device by including only sub-pixels that emit light of the same color in one sub-display area. For example, it may be possible to relatively reduce the difficulty of the process of fabricating a display device because the display device can be fabricated using an open mask without using a high-resolution FMM (fine metal mask).

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of some embodiments of the present disclosure will become more apparent by describing in more detail aspects of some embodiments thereof with reference to the attached drawings, in which:

FIG. 1 is a perspective view of a display device according to some embodiments of the present disclosure;

FIG. 2 is a layout diagram of the first display of FIG. 1;

FIG. 3 is a layout diagram of the display areas of FIG. 2;

FIG. 4 is a layout diagram of the display areas of FIG. 3;

FIG. 5 is a cross-sectional view taken along the line P-P′ of FIG. 4;

FIG. 6 is a cross-sectional view taken along the line Q - Q′ of FIG. 4;

FIG. 7 is a cross-sectional view taken along the line R-R′ of FIG. 4;

FIG. 8 is a cross-sectional view taken along the line S-S′ of FIG. 4;

FIG. 9 is a cross-sectional view taken along the line T-T′ of FIG. 4;

FIG. 10 is a view showing an example of using the display device shown in FIG. 1;

FIGS. 11 and 12 are views showing examples for illustrating the sub-display areas and the image seen by a user.

### DETAILED DESCRIPTION

Aspects and features of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected.

Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

Specific embodiments are described below with reference to the attached drawings.

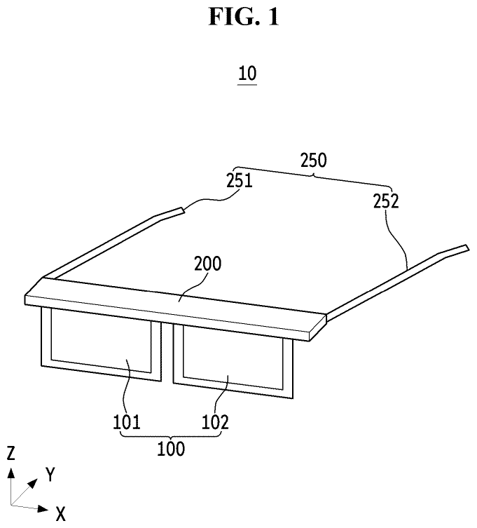

FIG. 1 is a perspective view of a display device according to some embodiments of the present disclosure.

Referring to FIG. 1, a display device 10 according to some embodiments of the present disclosure includes a display unit 100, a frame housing 200, and temples 250.

The display unit 100 may include a first display 101 and a second display 102. The first display 101 may face the user's right eye, and the second display 102 may face the user's left eye. Each of the first display 101 and the second display 102 may include a transparent material such as glass and plastic. Accordingly, a user can see a real-world image through the first display 101 and the second display 102.

The first display 101 and the second display 102 may be formed in, but is not limited to, a cuboidal shape. The first display 101 and the second display 102 may also be formed in other shapes such as a cylinder, an elliptical cylinder, and a polyhedron.

The frame housing 200 may be connected to the upper part of the first display 101 and the upper part of the second display 102. The frame housing 200 may be seen as the frame of the display unit 100 when the user wears the display device 10. Devices for driving the display unit 100 (e.g., an integrated circuit, a data driver unit, a battery, etc.) may be located inside the frame housing 200.

The temples 250 may be connected to the both ends of the frame housing 200. A first temple 251 may be coupled with one end of the frame housing 200. A second temple 252 may be coupled with the other end of the frame housing 200. Devices for driving the display unit 100 (e.g., an integrated circuit, a data driver unit, a battery, etc.) may be located inside the temples 250.

As used herein, the first direction (x-axis direction) may be the width direction of the first display 101 and the second display 102, the second direction (y-axis direction) may be the thickness direction of the first display 101 and the second display 102, and the three direction (z-axis direction) may be the height direction of the first display 101 and the second display 102.

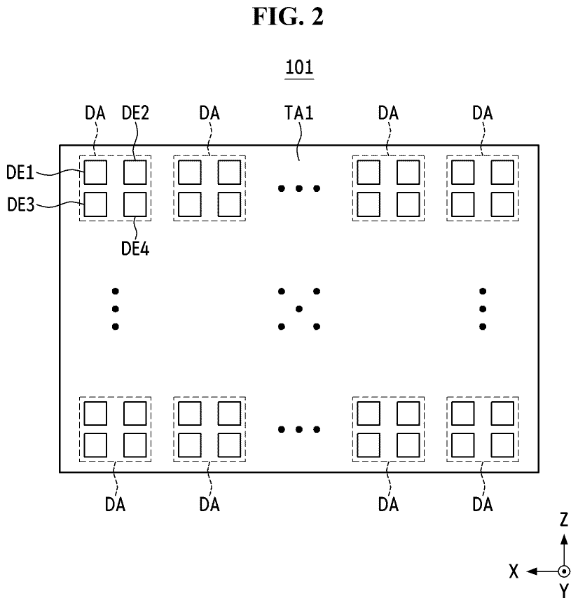

FIG. 2 is a layout diagram of the first display of FIG. 1.

The configuration of the second display 102 may be identical (or substantially identical) to that of the first display 101. Accordingly, only the first display 101 will be described for convenience of illustration.

The first display 101 includes a plurality of display areas DA, and a first transmissive area TA1 between the plurality of display areas DA.

The display areas DA are for displaying images by means of light-emitting elements. The display areas DA may be arranged in a matrix in the first display 101. The display areas DA may be spaced apart from one another.

Each of the display areas DA may include a plurality of sub-display areas. For example, each of the display areas DA may include first to fourth sub-display areas DE1 to DE4.

The first to fourth sub-display areas DE1 to DE4 may be arranged in a matrix. A second sub-display area DE2 may be located on the opposite side of the first sub-display area DE1 in the first direction (x-axis direction). A third sub-display area DE3 may be located on the opposite side of the first sub-display area DE1 in the third direction (z-axis direction). A fourth sub-display area DE4 may be located on the opposite side of the third sub-display area DE3 in the first direction (x-axis direction). It is to be understood that the above-described layout is merely illustrative and may be modified. For example, the first to fourth sub-display areas DE1 to DE4 may be arranged sequentially in the first direction (x-axis direction) or arranged sequentially in the third direction (z-axis direction).

The first transmissive area TA1 may be located between the display areas DA. The first transmissive area TA1 may be adjacent to the display areas DA.

The first transmissive area TA1 may transmit light traveling from the outside to display a real-world image. Because the first transmissive area TA1 includes a transparent material such as glass and plastic, the user can see a real-world image outside the display device 10 through the first transmissive area TA1.

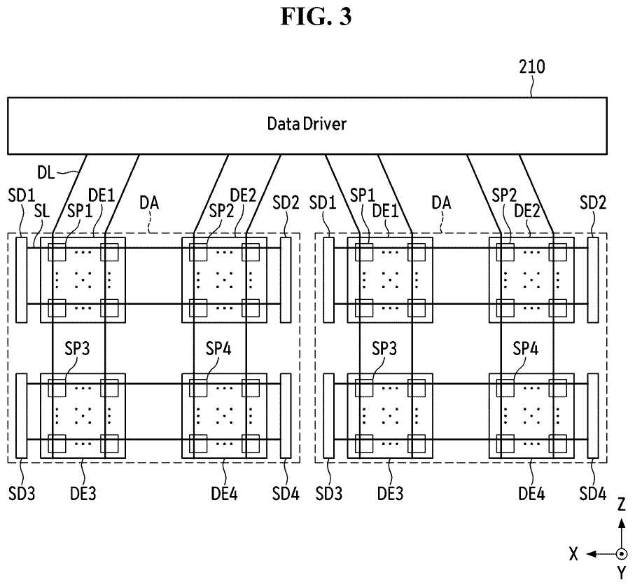

FIG. 3 is a layout diagram of the display areas of FIG. 2.

Referring to FIG. 3, each of the plurality of display areas DA may include first to fourth sub-display areas DE1 to DE4, first to fourth scan drivers SD1 to SD4, data lines DL, and scan lines SL. In addition, the display device 10 may include a data driver 210 and data lines DL.

The first to fourth sub-display areas DE1 to DE4 may include sub-pixels SP1 to SP4. The first sub-display area DE1 may include first sub-pixels SP1 that emit first light. The second sub-display area DE2 may include second sub-pixels SP2 that emit second light. The third sub-display area DE3 may include third sub-pixels SP3 that emit third light. The fourth sub-display area DE4 may include fourth sub-pixels SP4 that emit fourth light. For example, the first color may be red, the second color and the third color may be green, and the fourth color may be blue.

For example, the first to fourth sub-display areas DE1 to DE4 may include only one type of sub-pixels. The first sub-display area DE1 may include only the first sub-pixels SP1. The second sub-display area DE2 may include only the second sub-pixels SP2. The third sub-display area DE3 may include only the third sub-pixels SP3. The fourth sub-display area DE4 may include only the fourth sub-pixels SP3.

The first to fourth scan drivers SD1 to SD4 may be arranged at the edges of the display areas DA, respectively. For example, the first scan driver SD1 and the third scan driver SD3 may be located at first-side edges of the display areas DA, respectively, and the second scan driver SD2 and the fourth scan driver SD4 may be located at second-side edges opposite to the first-side edges of the display areas DA, respectively. For example, the first scan driver SD1 may be located on the side of the first sub-display area DE1 in the first direction (x-axis direction). The second scan driver SD2 may be located on the opposite side of the second sub-display area DE2 in the first direction (x-axis direction). The third scan driver SD3 may be located on the side of the third sub-display area DE3 in the first direction (x-axis direction). The fourth scan driver SD4 may be located on the opposite side of the fourth sub-display area DE4 in the first direction (x-axis direction).

The first to fourth scan drivers SD1 to SD4 may receive scan timing signals from a timing controller. The first to fourth scan drivers SD1 to SD4 may generate scan signals in response to the timing signals and sequentially output them to the scan lines SL.

The scan lines SL may connect the scan drivers SD1 to SD4 with the sub-pixels SP1 to SP4. The scan lines SL may be arranged in the first direction (x-axis direction) in each of the plurality of display areas DA, but the embodiments of the present disclosure are not limited thereto.

Each of the sub-pixels SP1 to SP4 may receive the data voltage from the data line DL according to the scan signal from the scan line SL, and may allow the light-emitting elements to emit light according to the data voltage.

The data driver 210 may be spaced apart from the plurality of display areas DA. The data driver 210 may be located inside the frame housing 200 and may be connected to the sub-pixels SP1 to SP4 through the data lines DL.

The data driver 210 may receive digital video data and a data timing signal from the timing controller. The data driver 210 may convert digital video data into analog data voltages in response to the data timing signal and output them to the data lines DL. In this instance, the sub-pixels SP1 to SP4 are selected by the scan signal, and the data voltages may be provided to the selected sub-pixels SP1 to SP4.

The data lines DL may connect the data driver 210 with the sub-pixels SP1 to SP4. The data lines DL may be arranged in the third direction (z-axis direction) inside the plurality of display areas DA, but the embodiments of the present disclosure are not limited thereto.

The timing controller may receive digital video data and timing signals from the outside. The timing controller may generate a scan timing signal and a data timing signal according to the timing signals. The timing controller may output the scan timing signal to the scan drivers SD1 to SD4 and output the digital video data and the data timing signal to the data driver 210.

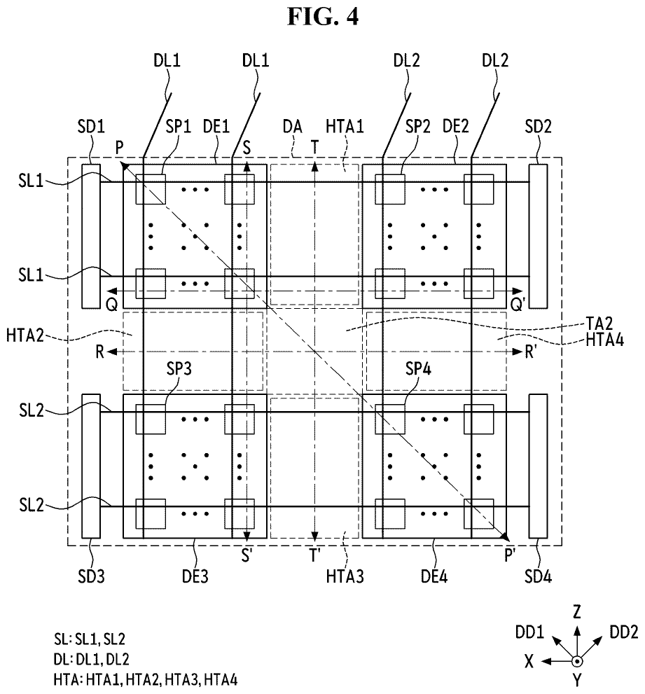

FIG. 4 is a layout diagram of the display areas of FIG. 3.

Referring to FIG. 4, the display area DA may further include first to fourth half-transmissive areas HTA1 to HTA4 and a second transmissive area TA2.

In the first to fourth sub-display areas DE1 to DE4, sub-pixels SP1 to SP4, data lines DL, and scan lines SL may be all arranged. Because the sub-pixels SP1 to SP4 are arranged in the first to fourth sub-display areas DE1 to DE4, light traveling from the outside may not easily pass through them.

In the half-transmissive areas HTA, one type of the data lines DL and the scan lines SL may be located. Because the sub-pixels SP1 to SP4 are not located in the half-transmissive areas HTA, light traveling from the outside may pass through them. It should be noted that one type of the data lines DL or the scan lines SL is located in the half-transmissive areas HTA, and thus light traveling from the outside is blocked by the data lines DL or the scan lines SL, and the half-transmissive areas HTA may only partially transmit the light traveling from the outside (or may transmit only a portion of a corresponding light traveling from the outside and incident thereto, with the remaining corresponding light being blocked by the corresponding data line DL or the corresponding scan line SL).

The half-transmissive areas HTA may include, for example, first to fourth half-transmissive areas HTA1 to HTA4. The first half-transmissive area HTA1 may be located between the first sub-display area DE1 and the second sub-display area DE2. The second half-transmissive area HTA2 may be located between the first sub-display area DE1 and the third sub-display area DE3. The third half-transmissive area HTA3 may be located between the third sub-display area DE3 and the fourth sub-display area DE4. The fourth half-transmissive area HTA4 may be located between the second sub-display area DE2 and the fourth sub-display area DE4.

The scan lines SL may include first scan lines SL1 and second scan lines SL2. The first scan lines SL1 may extend in the first direction (x-axis direction) and may be connected to first sub-pixels SP1, second sub-pixels SP2, a first scan driver SD1, and a second scan driver SD2. The first scan lines SL1 may be located in the first half-transmissive area HTA1. The second scan lines SL2 may extend in the first direction (x-axis direction) and may be connected to third sub-pixels SP3, fourth sub-pixels SP4, a third scan driver SD3, and a fourth scan driver SD4. The second scan lines SL2 may be located in the third half-transmissive area HTA3.

The data lines DL may include first data lines DL1 and second data lines DL2. The first data lines DL1 may extend in the third direction (z-axis direction) and may be connected to the first sub-pixels SP1, the third sub-pixels SP3, and the data driver 210. The first data lines DL1 may be located in the second half-transmissive area HTA2. The second data lines DL2 may extend in the third direction (z-axis direction) and may be connected to the second sub-pixels SP2, the fourth sub-pixels SP4, and the data driver 210. The second data lines DL2 may be located in the fourth half-transmissive area HTA4.

In the second transmissive area TA2, the sub-pixels SP1 to SP4, the data lines DL, and the scan lines SL may not be located. Accordingly, the second transmissive area TA2 may transmit light traveling from the outside. The second transmissive area TA2 may be located between the first half-transmissive area HTA1 and the third half-transmissive area HTA3, and between the second half-transmissive area HTA2 and the fourth half-transmissive area HTA4. The second transmissive area TA2 may be surrounded by the first to fourth half-transmissive areas HTA1 to HTA4.

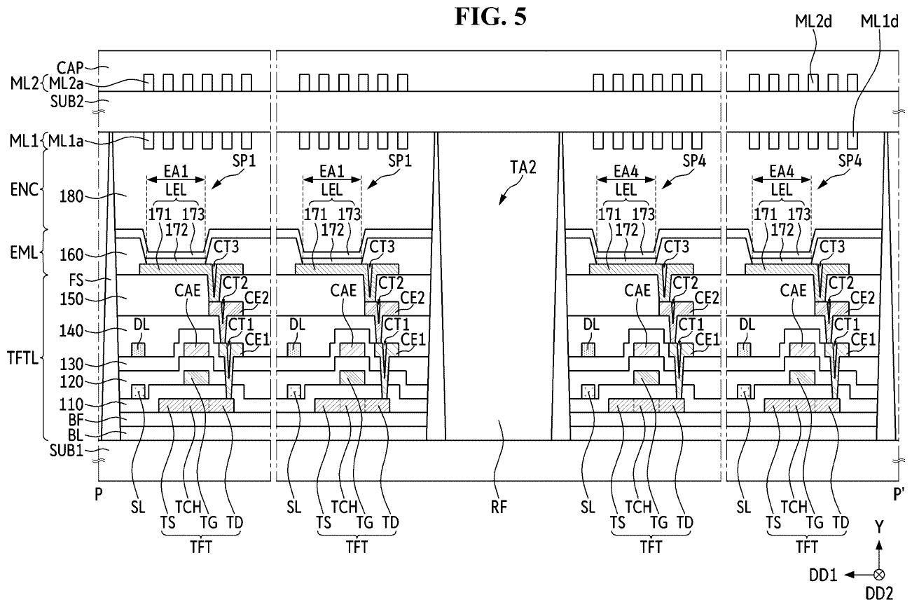

FIG. 5 is a cross-sectional view taken along the line P-P′ of FIG. 4.

Referring to FIG. 5, the first display 101 may include a first substrate SUB1, a thin-film transistor layer TFTL, an light emitting layer EML, an encapsulation layer ENC, lower metalenses ML1, a second substrate SUB2, upper metalenses ML2, and a protective layer CAP.

The thin-film transistor layer TFTL includes an active layer, a first gate layer, a second gate layer, a first data metal layer, and a second data metal layer. In addition, the thin-film transistor layer TFTL includes a light-blocking layer BL, a buffer film BF, a gate insulator 110, a first interlayer dielectric film 120, a second interlayer dielectric film 130, a first planarization film 140, and a second planarization film 150. The thin-film transistor layer TFTL includes a plurality of thin-film transistors TFT.

Each of the thin-film transistors includes a channel TCH, a gate electrode TG, a first electrode TS and a second electrode TD.

The light-blocking layer BL may be located on the first substrate SUB1 in some of the plurality of display areas DA. For example, the light-blocking layer BL may be located on the first substrate (SUB1) in the first sub-display area DE1 and the fourth sub-display area DE4. The light-blocking layer BL can block light incident on the thin-film transistor TFT. The light-blocking layer BL may not be located in the second transmissive area TA2.

The buffer film BF may be located on the light-blocking layer BL. The buffer film BF may be located in the first sub-display area DE1 and the fourth sub-display area DE4. On the other hand, the buffer film BF may not be located in the second transmissive area TA2.

The active layer may be located on the buffer film BF. The active layer may include silicon semiconductor such as polycrystalline silicon, monocrystalline silicon and low-temperature polycrystalline silicon, or may include oxide semiconductor.

The active layer may include a channel TCH, a first electrode TS and a second electrode TD of each of the thin-film transistors TFT. The channel TCH may be a region overlapping with the gate electrode TG of the thin-film transistor TFT in the second direction (y-axis direction), which is the thickness direction of the first substrate SUB1. The first electrode TS may be located on one side of the channel TSC, and the second electrode TD may be located on the opposite side of the channel TCH. The first electrode TS and the second electrode TD may be regions that do not overlap with the gate electrode TG in the second direction (y-axis direction). The first electrode TS and the second electrode TD may be regions having conductivity by doping ions in a silicon semiconductor or an oxide semiconductor.

The gate insulator 110 may be located on the active layer. The gate insulator 110 may be formed of an inorganic layer, for example, a silicon nitride layer, a silicon oxynitride layer, a silicon oxide layer, a titanium oxide layer, or an aluminum oxide layer.

The first gate layer may be located on the gate insulator 110. The first gate layer may include the gate electrode TG of each of a plurality of thin-film transistors TFT and the scan lines SL. The first gate layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 120 may be located on the first gate layer. The first interlayer dielectric film 120 may be formed of an inorganic layer, for example, a silicon nitride layer, a silicon oxynitride layer, a silicon oxide layer, a titanium oxide layer, or an aluminum oxide layer.

The second gate layer may be located on the first interlayer dielectric film 120. The second gate layer may include a capacitor electrode CAE. For example, the capacitor electrode CAE may overlap with the gate electrode TG in the second direction (y-axis direction). The second gate layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric film 130 may be located on the second gate layer. The second interlayer dielectric film 130 may be formed of an inorganic layer, for example, a silicon nitride layer, a silicon oxynitride layer, a silicon oxide layer, a titanium oxide layer, or an aluminum oxide layer.

A first data metal layer DTL1 may be located on the second interlayer dielectric film 130. The first data metal layer DTL1 may include a first connection electrode CE1 and data lines DL. The first connection electrode CE1 may be connected to the first electrode TS or the second electrode TD of the thin-film transistor TFT through a first contact hole CT1 penetrating the gate insulator 110, the first interlayer dielectric film 120 and the second interlayer dielectric film 130. The first data metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization film 140 may be located on the first data metal layer to provide a flat surface over the active layer ACT, the first gate layer GTL1, the second gate layer GTL2, and the first data metal layer DTL having different heights. The first planarization film 140 may be formed of an organic layer such as an acryl resin, an epoxy resin, a phenolic resin, a polyamide resin and a polyimide resin.

A second data metal layer may be located on the first planarization film 140. The second data metal layer may include a second connection electrode CE2. The second connection electrode CE2 may be connected to the first connection electrode CE1 through a second contact hole CT2 penetrating the first planarization film 140. The second data metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization film 150 may be located on the second data metal layer. The second planarization film 150 may be formed as an organic layer such as an acryl resin, an epoxy resin, a phenolic resin, a polyamide resin and a polyimide resin.

An light emitting layer EML may be located on the second planarization film 150. The light emitting layer EML may include a plurality of light-emitting elements LEL and a pixel-defining film 160. Each of the light-emitting elements LEL may be, but is not limited to, an organic light-emitting diode including a pixel electrode 171, an emissive layer 172 and a common electrode 173.

The pixel electrode 171 may be located on the second planarization film 150. The pixel electrode 171 may be connected to the second connection electrode CE2 through a third contact hole CT3 penetrating the second planarization film 150.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

The pixel-defining layer 160 may be located on the second planarization film 150 to cover the edges of each of the pixel electrodes 171 in order to define the light emitting areas EA. The pixel-defining film 160 may be formed of an organic layer such as an acryl resin, an epoxy resin, a phenolic resin, a polyamide resin and a polyimide resin.

In each of the light emitting areas EA, the pixel electrode 171, the emissive layer 172 and the common electrode 173 are stacked on one another sequentially, so that holes from the pixel electrode 171 and electrons from the common electrode 173 are recombined in the emissive layer 172 to emit light.

The emissive layer 172 may be located on the pixel electrode 171. The emissive layer 172 may include an organic material to emit light of a certain color. For example, the emissive layer 172 may include a hole transporting layer, an organic material layer, and an electron transporting layer.

The common electrode 173 may be located on the emissive layer 172. The common electrode 173 may be arranged to cover the emissive layer 172. The common electrode 173 may be a common layer formed across the light emitting areas EA.

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

An encapsulation layer 180 may be located on the common electrode 173. The encapsulation layer 180 can prevent or reduce contaminants such as oxygen or moisture permeating into the light emitting layer EML. The encapsulation layer 180 may include a material that can transmit light emitted from the light emitting layer EML.

The lower metalenses ML1 may be arranged on the encapsulation layer 180. The lower metalenses ML1 may overlap with the first sub-pixels SP1 and the fourth sub-pixels SP4 in the second direction (y-axis direction).

The metalenses ML1 and ML2 may include nanostructures. The metalenses ML1 and ML2 may adjust the phase of light by utilizing the refractive index difference between the nanostructures and the material in contact with the nanostructures. Accordingly, the metalenses ML1 and ML2 can modify the light path with a smaller thickness and lighter weight than existing refractive index lenses.

The spacing, width and height of the nanostructures may vary depending on the wavelength of light whose optical path is to be modified in the metalenses ML1 and ML2. For example, the width, length and/or diameter of the nanostructures may range from 300 nm to 800 nm for visible light. The nanostructures may have a size smaller than the wavelength of light passing through the metalenses ML1 and ML2. In this manner, nanostructures may form a meta surface and locally adjust the phase, intensity, and polarization of light.

A first lower metalens ML1a located in the first sub-display area DE1 and overlapping with the first sub-pixels SP1 may include first nanostructures having the first spacing, the first width, and the first height. The first nanostructures may have the same first spacing, first width and first height, or may have the first spacing, first width and first height according to a particular pattern. A fourth lower metalens ML1d located in the fourth sub-display area DE4 and overlapping with the fourth sub-pixels SP4 may include fourth nanostructures having the fourth spacing, the fourth width, and the fourth height. The fourth nanostructures may have the same fourth spacing, fourth width and fourth height, or may have the fourth spacing, fourth width and fourth height according to a particular pattern.

For example, the lower metalenses ML1 may work as a collimator that modifies the light path so that the light emitted from the emissive layer 172 propagates in parallel. Because the refractive index differs depending on the wavelength of light, the specific design of the lower metalenses ML1 may be changed depending on the color of the light emitted from the light emitting areas EA1 to EA4. The first spacing, first width and first height of the first nanostructures of the first lower metalens ML1a may be different from the fourth spacing, fourth width and fourth height of the fourth nanostructures of the fourth lower metalens ML2d.

The second substrate SUB2 may be located on the lower metalenses ML1. The second substrate SUB2 may include a material that allows light traveling from the outside to pass through it.

The upper metalenses ML2 may be located on the second substrate SUB2. The upper metalenses ML2 may overlap the lower metalenses ML1 in the second direction (y-axis direction).

A first upper metalens ML2a located in the first sub-display area DE1 may overlap with the first lower metalenses ML1a and the first sub-pixels SP1 in the second direction (y-axis direction). The first upper metalens ML2a may include fifth nanostructures having a fifth spacing, a fifth width, and a fifth height. The fifth nanostructures may have the same fifth spacing, fifth width and fifth height, or may have the fifth spacing, fifth width and fifth height according to a particular pattern.

A fourth upper metalens ML2d located in the fourth sub-display area DE4 may overlap with the fourth lower metalenses ML1d and the fourth sub-pixels SP4 in the second direction (y-axis direction). The fourth upper metalens ML2d may include eighth nanostructures having an eighth spacing, an eighth width, and an eighth height. The eighth nanostructures may have the same eighth spacing, eighth width and eighth height, or may have the eighth spacing, eighth width and eighth height according to a particular pattern.

For example, the upper metalenses ML2 may work as focusing lenses that adjust the focus of light emitted from each of the light emitting areas EA1 to EA4. Because the refractive index differs depending on the wavelength of light, the specific design of the upper metalenses ML2 may be changed depending on the color of the light emitted from the light emitting areas EA1 to EA4. In addition, although the first to fourth sub-display areas DE1 to DE4 in the first display 101 each include only the same sub-pixels SP1 to SP4, respectively, the upper metalenses ML2 may adjust the focal position of each of the sub-pixels SP1 to SP4 so that the sub-pixels SP1 to SP4 are mixed in the user's field of view.

The fifth spacing, fifth width and fifth height of the fifth nanostructures of the first upper metalens ML2a may be different from the eighth spacing, eighth width and eighth height of the eighth nanostructures of the fourth upper metalens ML2d.

The protective layer CAP may be arranged over the second substrate SUB2 and the upper metalenses ML2. The protective layer CAP can protect the upper metalenses ML2. In addition, the protective layer CAP may allow light passing through the upper metalens ML2a to be refracted by a difference in refractive index with the upper metalens ML2a. The protective layer CAP may include a material having a low refractive index so that light passing through the upper metalens ML2a can be effectively refracted. For example, the protective layer CAP may include at least one of silicon oxide, zirconium oxide, or hollow silica. In addition, the protective layer CAP may further include an additional optical film.

In the example shown in FIG. 5, the size of the first light emitting area EA1 is equal to the size of the fourth light emitting area EA4. The first light emitting area EA1 may be a red light emitting area, and the fourth light emitting area EA4 may be a blue light emitting area. It should be understood, however, that the relative sizes of the light emitting areas are not limited thereto. The size of the first light emitting area EA1 may be larger or smaller than the size of the fourth light emitting area EA4.

In addition, the first display 101 may further include a bonding portion FS and a refractive-index compensation layer RF.

The bonding portion FS may be located between the first substrate SUB1 and the second substrate SUB2. The bonding portion FS may bond the first substrate SUB1 with the second substrate SUB2. The bonding portion FS may be formed by melting the same material as the first substrate SUB1 and the second substrate SUB2 to bond the first substrate SUB1 to the second substrate SUB2 with it. For example, when the first substrate SUB1 and the second substrate SUB2 are glass substrates, the bonding portion FS may be frit glass melted and bonded to the first substrate SUB1 and the second substrate SUB2.

The bonding portion FS may be located at the edges of the plurality of display areas DA. The bonding portion FS may be located at a part of the edges of the first sub-display area DE1. In addition, the bonding portion FS may be located at a part of the edges of the fourth sub-display area DE4. The bonding portion FS may be located on the side and the opposite side of the first sub-display area DE1 in a fourth direction DD1. The bonding portion FS may be located on the side and the opposite side of the fourth sub-display area DE4 in the fourth direction DD1.

Referring to FIG. 4, the bonding portion FS may be located on the upper side and the left side of the first sub-display area DE1. The bonding portion FS may be located on the lower side and the right side of the fourth sub-display area DE4.

In addition, the bonding portion FS may be located between one of the sub-display areas DE1 to DE4 and the second transmissive area TA2, and between one of the half-transmissive areas HTA and the second transmissive area TA2.

The bonding portion FS may be located between the first sub-display area DE1 and the second transmissive area TA2 at the lower right corner of the first sub-display area DE1. The bonding portion FS may be located between the second sub-display area DE2 and the second transmissive area TA2 at the lower left corner of the second sub-display area DE2. The bonding portion FS may be located between the third sub-display area DE3 and the second transmissive area TA2 at the upper right corner of the third sub-display area DE3. The bonding portion FS may be located between the fourth sub-display area DE4 and the second transmissive area TA2 at the upper left corner of the fourth sub-display area DE4.

The bonding portion FS may be located between the first half-transmissive area HTA1 and the second transmissive area TA2 on the lower side of the first half-transmissive area HTA1. The bonding portion FS may be located between the second half-transmissive area HTA2 and the second transmissive area TA2 on the right side of the second half-transmissive area HTA2. The bonding portion FS may be located between the third half-transmissive area HTA3 and the second transmissive area TA2 on the upper side of the third half-transmissive area HTA3. The bonding portion FS may be located between the fourth half-transmissive area HTA4 and the second transmissive area TA2 on the left side of the fourth half-transmissive area HTA4.

The refractive-index compensation layer RF may be located between the first substrate SUB1 and the second substrate SUB2 in the second transmissive area TA2. The refractive-index compensation layer RF may have the refractive index equal (or substantially equal) to that of the first substrate SUB1 and the second substrate SUB2. For example, a difference in the refractive index between the refractive-index compensation layer RF and the first substrate SUB1 may be equal to or less than 0.1. The difference in the refractive index between the refractive-index compensation layer RF and the second substrate SUB2 may be equal to or less than 0.1. In this manner, by suppressing the refraction that occurs between the first substrate SUB1 and the second substrate SUB2, it may be possible to reduce light incident on the display device 10 from the outside from appearing double to the user or being distorted due to refraction.

Although the upper end of the bonding portion FS is narrower than the lower end in the drawings, the embodiments of the present disclosure are not limited thereto.

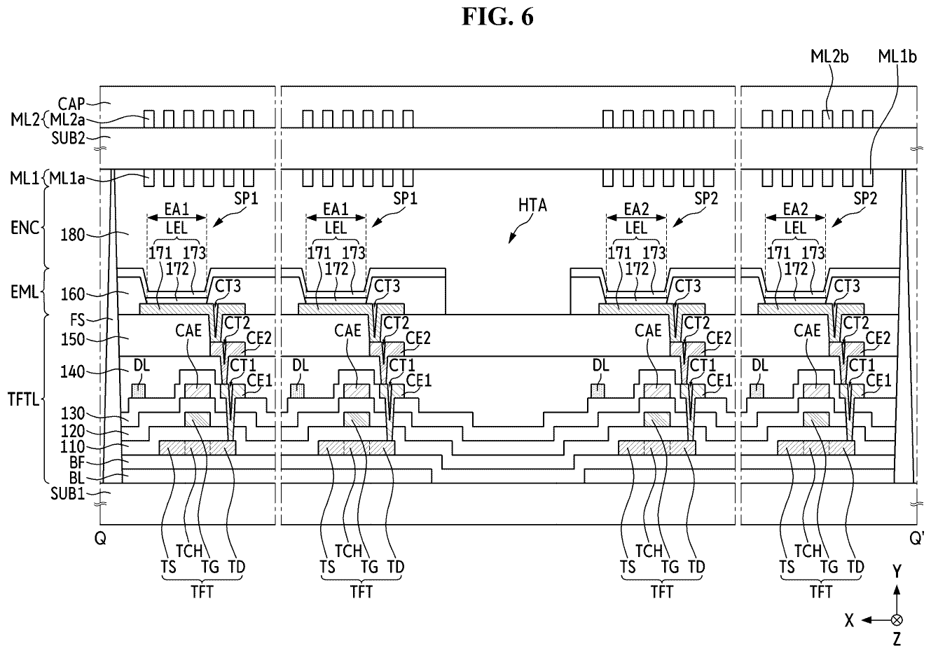

FIG. 6 is a cross-sectional view taken along the line Q-Q′ of FIG. 4. The following description will focus on differences and some redundant description may be omitted.

Referring to FIG. 6, in a second sub-display area DE2, the first display 101 may include a first substrate SUB1, a thin-film transistor layer TFTL, an light emitting layer EML, an encapsulation layer ENC, lower metalenses ML1, a second substrate SUB2, upper metalenses ML2, and a protective layer CAP.

The stacked structure of the thin-film transistor layer TFTL, the light emitting layer EML and the encapsulation layer ENC in the second sub-display area DE2 may be identical (or substantially identical) to the stacked structure of the thin-film transistor layer TFTL, the light emitting layer EML and the encapsulation layer ENC in the first sub-display area DE1 described above with reference to FIG. 5.

In the example shown in FIG. 6, the size of the first light emitting area EA1 is equal to the size of the second light emitting area EA2. The first light emitting area EA1 may be a red light emitting area, and the second light emitting area EA2 may be a green light emitting area. It should be understood, however, that the relative sizes of the light emitting areas are not limited thereto. The size of the first light emitting area EA1 may be larger or smaller than the size of the second light emitting area EA2.

A second lower metalens ML1b may be located on the encapsulation layer 180 in the second sub-display area DE2. The second lower metalens ML1b may overlap with the second sub-pixels SP2. The second lower metalens ML1b may include second nanostructures having a second spacing, a second width, and a second height. The second nanostructures may have the same second spacing, second width and second height, or may have the second spacing, second width and second height according to a particular pattern.

For example, the second lower metalens ML1b may work as a collimator that modifies the light path so that the light emitted from the second light emitting area EA2 propagates in parallel. Lights of different wavelengths have different refractive indexes, the specific structure of the second lower metalens ML1b may be different from the structure of the first lower metalens ML1a. The second spacing, second width and second height of the second nanostructures of the second upper metalens ML1b may be different from the first spacing, first width and first height of the first nanostructures of the first lower metalens ML1a.

The second substrate SUB2 may be located on the second lower metalens ML1b, and a second upper metalens ML2b may be located on the second substrate SUB2. The second upper metalens ML2b may overlap with the second lower metalenses ML1b and the second sub-pixels SP2 in the second direction (y-axis direction). The second upper metalens ML2b may include sixth nanostructures having a sixth spacing, a sixth width, and a sixth height. The sixth nanostructures may have the same sixth spacing, sixth width and sixth height, or may have the sixth spacing, sixth width and sixth height according to a particular pattern.

For example, the second upper metalens ML2b may act as a focus lens that adjusts the focus of light emitted from the second light emitting area EA2. Because lights of different wavelengths have different refractive indexes, the sixth spacing, the sixth width and the sixth height of the sixth nanostructures of the second upper metalens ML2b may be different from the fifth spacing, the fifth width and the fifth height of the fifth nanostructures of the first upper metalens ML1a.

In addition, although the first to fourth sub-display areas DE1 to DE4 in the first display 101 each include only the same sub-pixels SP1 to SP4, respectively, the upper metalenses ML2 may adjust the focal position of each of the sub-pixels SP1 to SP4 so that the sub-pixels SP1 to SP4 are mixed in the user's field of view.

The bonding portion FS may be located at a part of the edges of the second sub-display area DE2. Referring to FIG. 4, the bonding portion FS may be located on the upper side and the right side of the second sub-display area DE2. The bonding portion FS may not be located between the second sub-display area DE2 and the half-transmissive areas HTA.

A buffer film BF may be located on the first substrate SUB1 in the half-transmissive area HTA. Because a light-blocking layer BL is not located in the half-transmissive area HTA, light traveling from the outside toward the first substrate SUB1 may transmit the first substrate SUB1.

A gate insulator 110 may be located on the buffer film BF in the half-transmissive area HTA. A first interlayer dielectric film 120 may be located on the gate insulator 110. A first gate layer including scan lines SL may be located on the first interlayer dielectric film 120. A second interlayer dielectric film 130 may be located on the first gate layer. A second gate layer including data lines DL may be located on the second interlayer dielectric film 130. A first planarization film 140 may be located on the second gate layer. A second planarization film 150 may be located on the first planarization film 140. An encapsulation layer 180 may be located on the second planarization film 150.

Because the light emitting areas EA1 to EA4 are not formed in the half-transmissive area HTA, the pixel-defining layer 160 may not be located. In addition, although the first planarization film 140 and the second planarization film 150 are located in the half-transmissive area HTA in the drawings, the first planarization film 140 and the second planarization film 150 may be eliminated in some implementations. In such case, the encapsulation layer 180 may be located on the second interlayer dielectric film 130 in the half-transmissive area HTA.

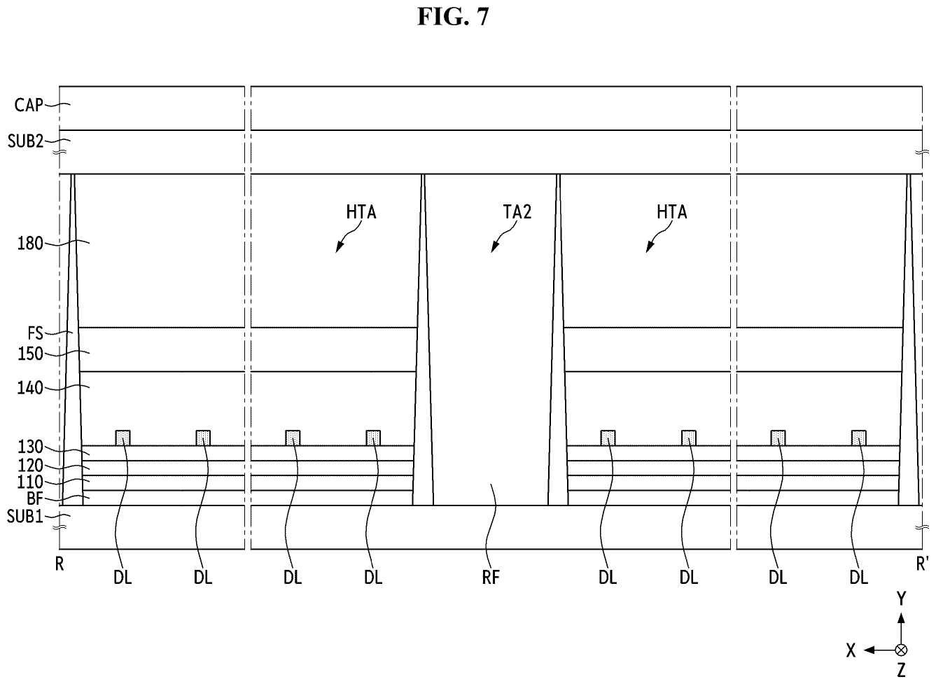

FIG. 7 is a cross-sectional view taken along the line R-R′ of FIG. 4. The following description will focus on differences and some redundant description may be omitted.

Referring to FIG. 7, data lines DL may be located in the half-transmissive area HTA. The stacked structure of the half-transmissive area HTA has been described above with reference to FIG. 6; and, therefore, some redundant descriptions may be omitted.

The bonding portion FS may be located at a part of the edges of the half-transmissive area HTA. Referring to FIG. 4, the bonding portion FS may be located on the upper side of the first half-transmissive area HTA1. The bonding portion FS may be located on the left side of the second half-transmissive area HTA2. The bonding portion FS may be located on the lower side of the third half-transmissive area HTA3. The bonding portion FS may be located on the right side of the fourth half-transmissive area HTA4.

The bonding portion FS may be located between the half-transmissive area HTA and the second transmissive area TA2. The bonding portion FS may be located between the first half-transmissive area HTA1 and the second transmissive area TA2 on the lower side of the first half-transmissive area HTA1. The bonding portion FS may be located between the second half-transmissive area HTA2 and the second transmissive area TA2 on the right side of the second half-transmissive area HTA2. The bonding portion FS may be located between the third half-transmissive area HTA3 and the second transmissive area TA2 on the upper side of the third half-transmissive area HTA3. The bonding portion FS may be located between the fourth half-transmissive area HTA4 and the second transmissive area TA2 on the left side of the fourth half-transmissive area HTA4.

Because the light-emitting elements LEL are not located in the half-transmissive area HTA or the second transmissive area TA2, the lower metalenses ML1 and the upper metalenses ML2 that adjust the path of light emitted from the light-emitting elements LEL may not be located in the half-transmissive area HTA or the second transmissive area TA2, either.

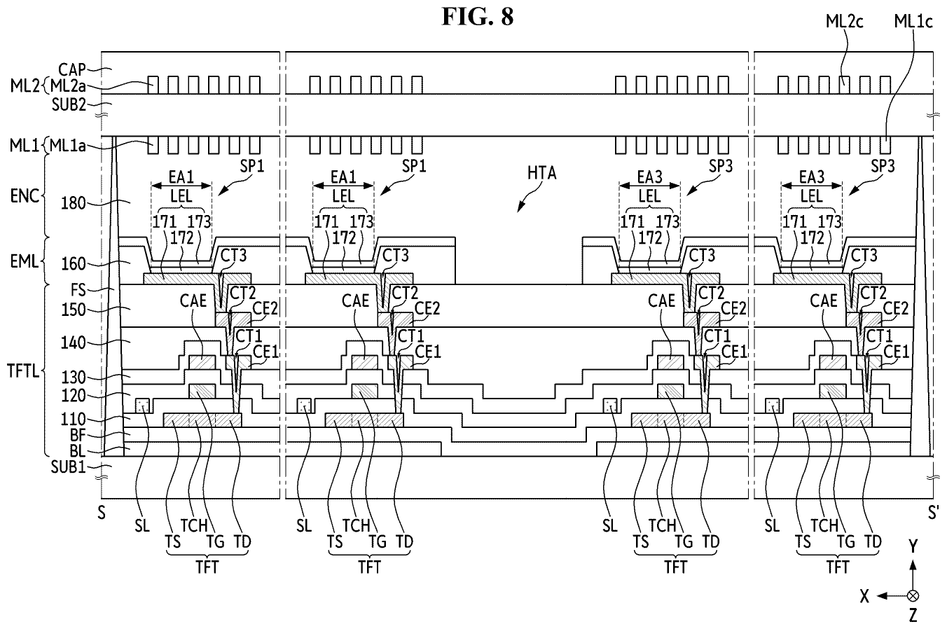

FIG. 8 is a cross-sectional view taken along the line S-S′ of FIG. 4. The following description will focus on differences and some redundant description may be omitted.

Referring to FIG. 8, in a third sub-display area DE3, the first display 101 may include a first substrate SUB1, a thin-film transistor layer TFTL, an light emitting layer EML, an encapsulation layer ENC, lower metalenses ML1, a second substrate SUB2, upper metalenses ML2, and a protective layer CAP.

The stacked structure of the thin-film transistor layer TFTL, the light emitting layer EML and the encapsulation layer ENC in the third sub-display area DE3 may be identical (or substantially identical) to the stacked structure of the thin-film transistor layer TFTL, the light emitting layer EML and the encapsulation layer ENC in the first sub-display area DE1 described above with reference to FIG. 5.

In the example shown in FIG. 8, the size of the third light emitting area EA3 is equal to the size of the first light emitting area EA1. The first light emitting area EA1 may be a red light emitting area, and the third light emitting area EA3 may be a green light emitting area. It should be understood, however, that the relative sizes of the light emitting areas are not limited thereto. The size of the first light emitting area EA1 may be larger or smaller than the size of the third light emitting area EA3.

A third lower metalens ML1c may be located on the encapsulation layer 180 in the third sub-display area DE3. The third lower metalens ML1c may overlap with the third sub-pixels SP3. The third lower metalens ML1c may include third nanostructures having a third spacing, a third width, and a third height. The third nanostructures may have the same third spacing, third width and third height, or may have the third spacing, third width and third height according to a particular pattern.

For example, the third lower metalens ML1c may work as a collimator that modifies the light path so that the light emitted from the third light emitting area EA3 propagates in parallel. Lights of different wavelengths have different refractive indexes, the specific structure of the third lower metalens ML1c may be different from the structure of the first lower metalens ML1a. The third spacing, third width and third height of the third nanostructures of the third lower metalens ML1c may be different from the first spacing, first width and first height of the first nanostructures of the first lower metalens ML1a.

The second substrate SUB2 may be located on the third lower metalens ML1c, and a third upper metalens ML2c may be located on the second substrate SUB2. The third upper metalens ML2c may overlap with the third lower metalenses ML1c and the third sub-pixels SP3 in the second direction (y-axis direction). The third lower metalens ML1c may include seventh nanostructures having a seventh spacing, a seventh width, and a seventh height. The seventh nanostructures may have the same seventh spacing, seventh width and seventh height, or may have the seventh spacing, seventh width and seventh height according to a particular pattern.

For example, the third upper metalens ML2c may act as a focus lens that adjusts the focus of light emitted from the third light emitting area EA3. Because lights of different wavelengths have different refractive indexes, the seventh spacing, the seventh width and the seventh height of the seventh nanostructures of the third upper metalens ML2c may be different from the fifth spacing, the fifth width and the fifth height of the fifth nanostructures of the first upper metalens ML1a.

In addition, although the first to fourth sub-display areas DE1 to DE4 in the first display 101 each include only the same sub-pixels SP1 to SP4, respectively, the upper metalenses ML2 may adjust the focal position of each of the sub-pixels SP1 to SP4 so that the sub-pixels SP1 to SP4 are mixed in the user's field of view.

The bonding portion FS may be located at a part of the edges of the third sub-display area DE3. Referring to FIG. 4, the bonding portion FS may be located on the left side and the lower side of the third sub-display area DE3. The bonding portion FS may not be located between the third sub-display area DE3 and the half-transmissive areas HTA.

The stacked structure of the half-transmissive area HTA has been described above with reference to FIG. 6; and, therefore, some redundant descriptions may be omitted.

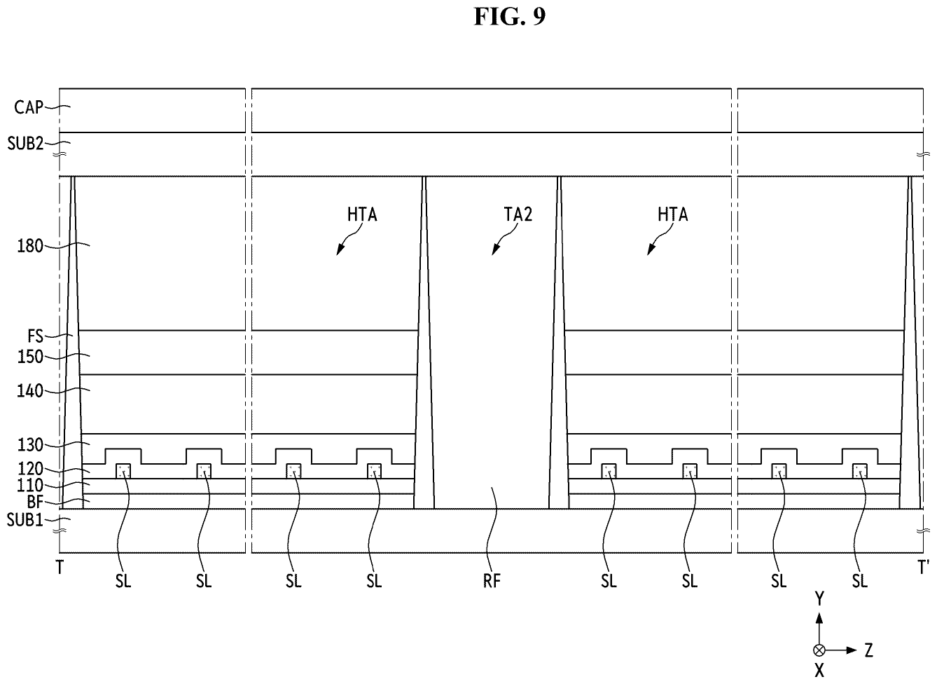

FIG. 9 is a cross-sectional view taken along the line T-T′ of FIG. 4. The following description will focus on differences and some redundant description may be omitted.

Referring to FIG. 9, scan lines SL may be located in the half-transmissive area HTA. The stacked structure of the half-transmissive area HTA has been described above with reference to FIG. 6; and, therefore, some redundant descriptions may be omitted.

The bonding portion FS may be located at a part of the edges of the half-transmissive area HTA. Referring to FIG. 4, the bonding portion FS may be located on the upper side of the first half-transmissive area HTA1. The bonding portion FS may be located on the left side of the second half-transmissive area HTA2. The bonding portion FS may be located on the lower side of the third half-transmissive area HTA3. The bonding portion FS may be located on the right side of the fourth half-transmissive area HTA4.

The bonding portion FS may be located between the half-transmissive area HTA and the second transmissive area TA2. The bonding portion FS may be located between the first half-transmissive area HTA1 and the second transmissive area TA2 on the lower side of the first half-transmissive area HTA1. The bonding portion FS may be located between the second half-transmissive area HTA2 and the second transmissive area TA2 on the right side of the second half-transmissive area HTA2. The bonding portion FS may be located between the third half-transmissive area HTA3 and the second transmissive area TA2 on the upper side of the third half-transmissive area HTA3. The bonding portion FS may be located between the fourth half-transmissive area HTA4 and the second transmissive area TA2 on the left side of the fourth half-transmissive area HTA4.

Although the cross-section of the second transmissive area TA2 only is shown in the drawing, the configuration of the first transmissive area TA1 may be identical (or substantially identical) to that of the second transmissive area TA2. The first transmissive area TA1 may also have a structure in which the first substrate SUB1, the refractive-index compensation layer RF, the second substrate SUB2, and the protective layer CAP are sequentially stacked on one another.

Although only two metalens layers including the lower metalenses ML1 and the upper metalenses ML2 are shown in the drawings, embodiments of the present disclosure are not limited thereto. In some other embodiments of the present disclosure, the display device may include three or more metalens layers for higher precision.

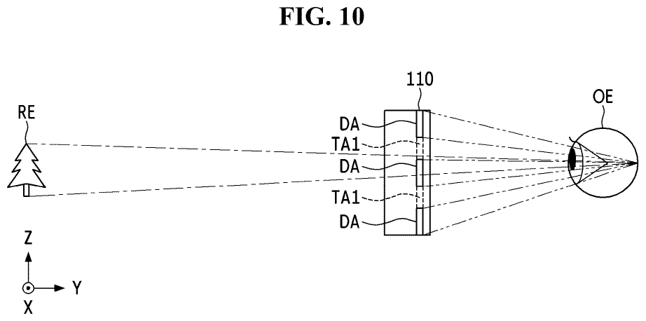

FIG. 10 is a view showing an example of using the display device shown in FIG. 1.

Referring to FIG. 10, a user OE may observe a virtual image displayed in the plurality of display areas DA of the first display 101. In addition, the user OE may observe a real-world image RE through the first transmissive area TA1 of the first display 101 and the second transmissive area TA2 of each of the plurality of display areas DA. In this manner, the display device 10 can display a virtual image and simultaneously (or concurrently) transmit a real-world image to provide it to the user, thereby allowing the user to experience augmented reality.

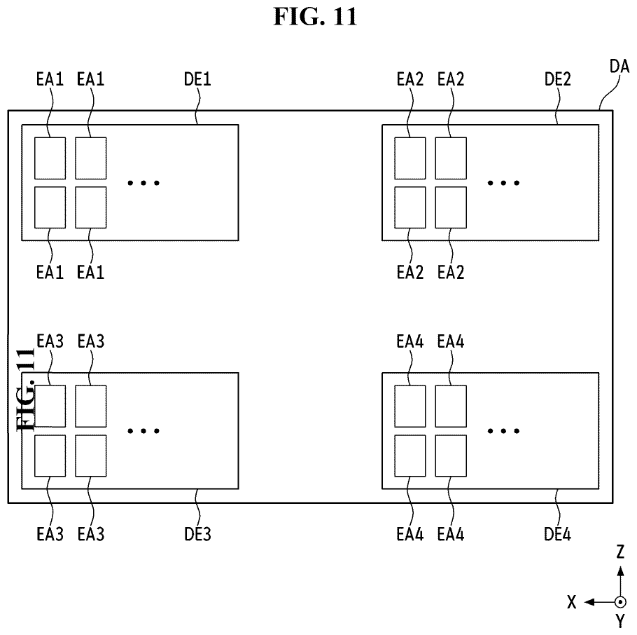

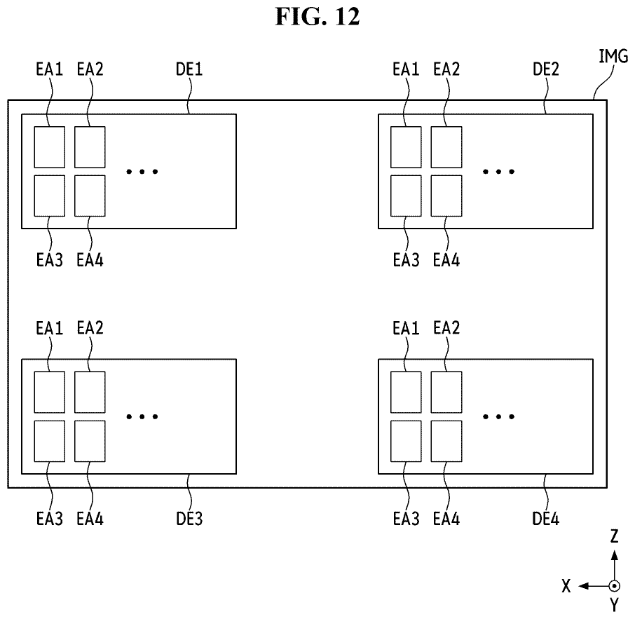

FIGS. 11 and 12 are views showing examples for illustrating the sub-display areas and the image seen by a user.

FIG. 11 shows light emitting areas EA1 to EA4 displayed in a single display area DA. FIG. 12 shows the light emitting areas EA1 to EA4 visible in an image IMG seen by the user.

Referring to FIG. 11, the sub-display areas DE1 to DE4 of the display area DA each include only one type of light emitting areas EA1 to EA4. The first sub-display area DE1 includes only the first light emitting areas EA1. The second sub-display areas DE2 include only the second light emitting areas EA2. The third sub-display areas DE3 include only the third light emitting areas EA3. The fourth sub-display areas DE4 include only the fourth light emitting areas EA4.

In contrast, referring to FIG. 12, the first to fourth light emitting areas EA1 to EA4 can be evenly observed in the image IMG seen by the user. For example, a second light emitting area EA2 may be located on the right side of a first light emitting area EA1 at the upper left end of the first sub-display area DE1. A third light emitting area EA3 may be located on the lower side of the first light emitting area EA1 at the upper left end of the first sub-display area DE1. A fourth light emitting area EA4 may be located on the right side of the third light emitting area EA3.

This utilizes the upper metalenses ML2 described above. The upper metalenses ML2 may be designed such that light travels along different optical paths for different light emitting areas EA1 to EA4 of the sub-pixels SP1 to SP4. To this end, the spacing, width and height of the upper metalenses ML2 may be set for each of the different sub-pixels SP1 to SP4.

Although aspects of some embodiments of the present disclosure have been described with reference to the accompanying drawings, those of ordinary skill in the art to which the present disclosure pertains will understand that the present disclosure may be embodied in other specific forms without changing the technical spirit or scope of embodiments thereof. Therefore, it should be understood that the embodiments described above are illustrative in all aspects and not restrictive.

What is claimed is:

1. A display device comprising:
a plurality of display areas; and
a first transmissive area between the plurality of display areas and configured to transmit light traveling from outside,
wherein each of the plurality of display areas comprises:
a first sub-display area comprising first sub-pixels configured to emit first light;
a second sub-display area comprising second sub-pixels configured to emit second light;
a third sub-display area comprising third sub-pixels configured to emit third light; and
a fourth sub-display area comprising fourth sub-pixels configured to emit fourth light.

2. The display device of claim 1, wherein each of the plurality of display areas comprises:
a first half-transmissive area between the first sub-display area and the second sub-display area and configured to transmit a first portion of the light traveling from the outside;
a second half-transmissive area between the first sub-display area and the third sub-display area and configured to transmit a second portion of the light traveling from the outside;
a third half-transmissive area between the third sub-display area and the fourth sub-display area and configured to transmit a third portion of the light traveling from the outside; and
a fourth half-transmissive area between the second sub-display area and the fourth sub-display area and configured to transmit a fourth portion of the light traveling from the outside.

3. The display device of claim 2, wherein each of the plurality of display areas further comprises: a second transmissive area, wherein the second transmissive area is between the first half-transmissive area and the third half-transmissive area, and between the second half-transmissive area and the fourth half-transmissive area, and configured to transmit the light traveling from the outside.

4. The display device of claim 3, wherein each of the plurality of display areas further comprises:
a first lower sub-metalens in the first sub-display area and comprising first nanostructures having a first spacing, a first width, and a first height; and
a first upper sub-metalens overlapping the first lower sub-metalens and comprising second nanostructures having a second spacing, a second width, and a second height.

5. The display device of claim 3, wherein each of the plurality of display areas further comprises:
a second lower sub-metalens in the second sub-display area and comprising third nanostructures having a third spacing, a third width, and a third height; and
a second upper sub-metalens overlapping the second lower sub-metalens and comprising fourth nanostructures having a fourth spacing, a fourth width, and a fourth height.

6. The display device of claim 3, wherein each of the plurality of display areas further comprises:
a third lower sub-metalens in the third sub-display area and comprising fifth nanostructures having a fifth spacing, a fifth width, and a fifth height; and
a third upper sub-metalens overlapping the third lower sub-metalens and comprising sixth nanostructures having a sixth spacing, a sixth width, and a sixth height.

7. The display device of claim 3, wherein each of the plurality of display areas further comprises:
a fourth lower sub-metalens in the fourth sub-display area and comprising seventh nanostructures having a seventh spacing, a seventh width, and a seventh height; and
a sixth upper sub-metalens overlapping the fourth lower sub-metalens and comprising eighth nanostructures having an eighth spacing, an eighth width, and an eighth height.

8. The display device of claim 2, wherein each of the plurality of display areas further comprises:
a first scan driver on a first side of the first sub-display area;
a second scan driver on a second side of the second sub-display area;
a third scan driver on a first side of the third sub-display area; and
a fourth scan driver on a second side of the fourth sub-display area,
wherein a first side of the second sub-display area faces a second side of the first sub-display area that is opposite to the first side, and
wherein a first side of the fourth sub-display area faces a second side of the third sub-display area that is opposite to the first side.

9. The display device of claim 8, further comprising:
first scan lines extending in a first direction and connected to the first sub-pixels, the second sub-pixels, the first scan driver and the second scan driver; and
second scan lines extending in the first direction and connected to the third sub-pixels, the fourth sub-pixels, the third scan driver, and the fourth scan driver.

10. The display device of claim 9, wherein the first scan lines are in the first half-transmissive area, and the second scan lines are in the third half-transmissive area.

11. The display device of claim 2, further comprising:
a data driver spaced apart from the plurality of display areas and the first transmissive area.

12. The display device of claim 11, further comprising:
first data lines extending in a second direction and connected to the first sub-pixels, the third sub-pixels, and the data driver; and
second data lines extending in the second direction and connected to the second sub-pixels, the fourth sub-pixels, and the data driver.

13. The display device of claim 12, wherein the first data lines are in the second half-transmissive area, and the second data lines are in the fourth half-transmissive area.

14. A display device comprising a plurality of display areas and a first transmissive area between the plurality of display areas, the display device comprising:
a first substrate;
a light-blocking layer on the first substrate in some of the plurality of display areas;
at least one thin-film transistor, scan lines and data lines on the light-blocking layer;
a planarization film on the thin-film transistor, the scan lines and the data lines;
a plurality of light emitting areas on the planarization film and each comprising a first electrode, an emissive layer and a second electrode;
an encapsulation layer on the light emitting areas;
a plurality of lower metalenses on the encapsulation layer in each of the plurality of display areas;
a second substrate on the plurality of lower metalenses; and
a plurality of upper metalenses on the second substrate.

15. The display device of claim 14, further comprising:
a refractive-index compensation layer between the first substrate and the second substrate in the first transmissive area and has a refractive index equal to that of the first substrate.

16. The display device of claim 15, wherein the plurality of display areas comprises a plurality of sub-display areas, a plurality of half-transmissive areas, and a second transmissive area, and
wherein the refractive-index compensation layer is further in the second transmissive area.

17. The display device of claim 16, wherein the refractive-index compensation layer does not overlap with the plurality of sub-display areas and the plurality of half-transmissive areas.

18. The display device of claim 16, further comprising:
a bonding portion between the first substrate and the second substrate to bond the first substrate with the second substrate.

19. The display device of claim 18, wherein the bonding portion is between one of the sub-display areas and the second transmissive area, and between one of the half-transmissive areas and the second transmissive area.

20. An electronic device including a display device, the display device comprising:
a plurality of display areas; and
a first transmissive area between the plurality of display areas and configured to transmit light traveling from outside,
wherein each of the plurality of display areas comprises:
a first sub-display area comprising first sub-pixels configured to emit first light;
a second sub-display area comprising second sub-pixels configured to emit second light;
a third sub-display area comprising third sub-pixels configured to emit third light; and
a fourth sub-display area comprising fourth sub-pixels configured to emit fourth light.
